(19) United States
(12) Patent Application Publication
(10) Pub. No.: US 2004/0124407 A1
(43) Pub. Date: Jul. 1, 2004

(54) Scalable programmable structure, an array including the structure, and methods of forming the same

(76) Inventors: Michael N. Kozicki, Phoenix, AZ (US); Maria Mitkova, Mesa, AZ (US); Chakravarthy Gopalan, Tempe, AZ (US)

Correspondence Address: SNELL & WILMER, ONE ARIZONA CENTER, 400 EAST VAN BUREN, PHOENIX, AZ, 850040001

(21) Appl. No.: 10/458,551

(22) Filed: Jun. 9, 2003

Related U.S. Application Data
(63) Continuation-in-part of application No. 10/390,268, filed on Mar. 17, 2003.
Application No. 10/390,268 is a continuation-in-part of application No. 10/268,107, filed on Oct. 9, 2002.
Application No. 10/268,107 is a continuation-in-part of application No. 10/118,276, filed on Apr. 8, 2002.
Application No. 10/118,276 is a continuation-in-part of application No. 09/502,915, filed on Feb. 11, 2000, now Pat. No. 6,487,106.
Application No. 10/118,276 is a continuation-in-part of application No. 09/951,882, filed on Sep. 10, 2001, now Pat. No. 6,635,914.
(60) Provisional application No. 60/387,204, filed on Jun. 7, 2002.
(60) Provisional application No. 60/390,793, filed on Jun. 19, 2002.

(51) Int. Cl. H01L 29/06

(52) U.S. Cl. 257/9

(57) ABSTRACT

A microelectronic programmable structure suitable for storing information, and array including the structure and methods of forming and programming the structure are disclosed. The programmable structure generally includes an ion conductor and a plurality of electrodes. Electrical properties of the structure may be altered by applying energy to the structure, and thus information may be stored using the structure.

### CROSS REFERENCE TO RELATED APPLICATIONS

This application is a continuation-in-part of U.S. patent application Ser. No. 10/390,268, entitled PROGRAMMABLE STRUCTURE, AN ARRAY INCLUDING THE STRUCTURE, AND METHODS OF FORMING THE SAME, filed Mar. 17, 2003, which is a continuation-in-part of application Ser. No. 10/268,107, entitled PROGRAMMABLE MICROELECTRONIC DEVICE, STRUCTURE, AND SYSTEM AND METHOD OF FORMING THE SAME, filed Oct. 9, 2002, which is a continuation-in-part of application Ser. No. 10/118,276 entitled MICROELECTRONIC DEVICE, STRUCTURE, AND SYSTEM, INCLUDING A MEMORY STRUCTURE HAVING A VARIABLE PROGRAMMABLE PROPERTY AND METHOD OF FORMING SAME, filed Apr. 9, 2002, which is a continuation-in-part of application Ser. No. 09/502,915, entitled PROGRAMMABLE MICROELECTRONIC DEVICES AND METHODS OF FORMING AND PROGRAMMING SAME, filed Apr. 19, 2000; and is a continuation-in-part of U.S. patent application Ser. No. 09/951,882, entitled MICROELECTRONIC PROGRAMMABLE DEVICE AND METHODS OF FORMING AND PROGRAMMING THE SAME, filed Sep. 10, 2001; and claims the benefit of U.S. patent application Ser. No. 60/387,204, entitled PROGRAMMABLE METALLIZATION CELL WITH INTEGRAL SERIES DIODE, filed Jun. 7, 2002 and U.S. patent application Ser. No. 60/390,793, entitled SOLID STATE ELECTROCHEMISTRY AND MEMORY SCALING June 19, 2002.

### 1. FIELD OF INVENTION

The present invention generally relates to programmable microelectronic devices. More particularly, the invention relates to programmable microelectronic structures and devices having an electrical property that can be programmed by manipulating an amount of energy supplied to the structure during a programming function and to memory arrays including the structures.

### 2. BACKGROUND OF THE INVENTION

Memory devices are often used in electronic systems and computers to store information in the form of binary data. These memory devices may be characterized into various types, each type having associated with it various advantages and disadvantages.

For example, random access memory (“RAM”), which may be found in personal computers, is typically volatile semiconductor memory; in other words, the stored data is lost if the power source is disconnected or removed. Dynamic RAM (“DRAM”) is particularly volatile in that it must be “refreshed” (i.e., recharged) every few hundred milliseconds in order to maintain the stored data. Static RAM (“SRAM”) will hold the data after one writing so long as the power source is maintained; once the power source is disconnected, however, the data is lost. Thus, in these volatile memory configurations, information is only retained so long as the power to the system is not turned off. In general, these RAM devices can take up significant chip area and therefore may be expensive to manufacture and consume relatively large amounts of energy for data storage. Accordingly, improved memory devices suitable for use in personal computers and the like and memory that allows for formation of a completely new architecture for such devices are desirable.

Reduced geometries in memory devices such as RAM and Flash memory devices have led to smaller devices and denser circuits and this has resulted in consistently higher system performance for lower cost. However, the semiconductor industry has publicly acknowledged that it faces ever-increasing difficulty in attaining the goals set forth in its own guide to future technological requirements, the International Technology Roadmap for Semiconductors (ITRS). The Roadmap has decreasing steps in feature size as its milestones and includes many operational targets, including reduced supply voltage and other critical factors such as minimized power dissipation. Unfortunately, it has become clear that the problems associated with physical and operational scaling are particularly acute for solid state memory, where current mainstream technologies such as DRAM and Flash have a very doubtful existence in anything like their current form beyond the middle of this decade. The reason for this is simple—scaling reduces the amount of charge that can be held in a cell so technologies that rely on this to store information can no longer do so in a reliable fashion when scaled beyond a certain limit, which is thought to lie around the 65 nm node. To make matters worse, scaling relies on reduced voltage and current in addition to shrinking feature size to attain higher packing density and memory technologies that rely on capacitive charging will not operate in an acceptable manner in this “low power” regime.

System performance and cost do not rely on dimensional scaling alone—component count and chip-to-chip interconnect bandwidth are also major factors. With this in mind it becomes obvious why the industry is pushing toward the system-on-chip (SoC) concept in which all solid state memory is embedded with logic on a single die so that fast and wide chip-level interconnect can be used and multiple components become one. However, the shortcomings of existing technologies are problematic because only SRAM can be readily integrated with logic and this is non-ideal as it occupies large amounts of the chip area and is susceptible to soft error problems at small dimensions. In addition, future embedded memory should be “universal”—it would be desirably as fast as SRAM or DRAM and also be non-volatile to retain data when all or part of the chip is powered down and to reduce power consumption.

The scaling quandary has led to an explosion in the development of alternative memory technologies and particularly of those which do not employ capacitive charge storage, ranging from magnetic storage in the relatively mature MRAM technology to the more exotic and futuristic NRAM which is based on carbon nanotubes. However, even though investment has been significant in the most promising cases, no new technology has been universally adopted by the industry due to non-ideal operational characteristics or difficulties in manufacturing and this has kept the door open for new contenders.

### SUMMARY OF THE INVENTION

The present invention provides improved microelectronic programmable devices, structures, and systems and methods of forming the same. More particularly, the invention provides programmable structures that can be variably programmed depending on an amount of energy used to program the device. Such structures can replace both traditional nonvolatile and volatile forms of memory and can be formed on the same substrate as and/or overlying another microelectronic device. Furthermore, the memory devices can be formed within an area having a diameter of less than 65 nm.

The ways in which the present invention addresses various drawbacks of now-known programmable devices are discussed in greater detail below. However, in general, the present invention provides a programmable device that is relatively easy and inexpensive to manufacture, which is relatively easy to program, and which can be variably programmed.

In accordance with one exemplary embodiment of the present invention, a programmable structure includes an ion conductor and at least two electrodes. The structure is configured such that when a bias is applied across two electrodes, one or more electrical properties of the structure change. In accordance with one aspect of this embodiment, a resistance across the structure changes when a bias is applied across the electrodes. In accordance with other aspects of this embodiment, a capacitance or other electrical property of the structure changes upon application of a bias across the electrodes. In accordance with a further aspect of this embodiment, an amount of change in the programmable property is manipulated by altering (e.g., thermally or electrically) an amount of energy used to program the device. One or more of these electrical changes and/or the amount of change may suitably be detected. Thus, stored information may be retrieved from a circuit including the structure.

In accordance with another exemplary embodiment of the invention, a programmable structure includes an ion conductor, at least two electrodes, and a barrier interposed between at least a portion of one of the electrodes and the ion conductor. In accordance with one aspect of this embodiment, the barrier material includes a material configured to reduce diffusion of ions between the ion conductor and at least one electrode. In accordance with another aspect, the barrier material includes an insulating or high-resistance material. In accordance with yet another aspect of this embodiment, the barrier includes material that conducts ions, but which is relatively resistant to the conduction of electrons.

In accordance with another exemplary embodiment of the invention, a programmable microelectronic structure is formed on a surface of a substrate by forming a first electrode on the substrate, depositing a layer of ion conductor material over the first electrode, and depositing conductive material onto the ion conductor material. In accordance with one aspect of this embodiment, a solid solution including the ion conductor and excess conductive material is formed by dissolving (e.g., via thermal and/or photodissolution) a portion of the conductive material in the ion conductor. In accordance with a further aspect, only a portion of the conductive material is dissolved, such that a portion of the conductive material remains on a surface of the ion conductor to form an electrode on a surface of the ion conductor material. In accordance with another aspect of this embodiment of the invention, a structure including a high-resistance region is formed by dissolving a portion of the electrode such that a portion of the ion conductor includes a high concentration of the electrode material and another portion of the ion conductor includes a low concentration of the electrode material, such that the portion of the ion conductor with a low concentration of the electrode material forms a high resistance region within the structure.

In accordance with another embodiment of the invention, a programmable device may be formed on a surface of a substrate. In accordance with one aspect of this embodiment, the substrate includes a microelectronic circuit. In accordance with a further aspect of this embodiment, the memory device is formed overlying the microelectronic circuit and conductive lines between the microelectronic circuit and the memory are formed using conductive wiring schemes within the substrate and the memory device. This configuration allows transmission of more bits of information per bus line.

In accordance with yet another embodiment of the invention, multiple programmable devices are coupled together using a common electrode (e.g., a common anode or a common cathode).

In accordance with yet a further exemplary embodiment of the present invention, a capacitance of a programmable structure is altered by causing ions within an ion conductor of the structure to migrate.

In accordance with yet another embodiment of the invention, a volatility of a memory cell in accordance with the present invention is manipulated by altering an amount of energy used during a write process for the memory. In accordance with this embodiment of the invention, higher energy is used to form nonvolatile memory, while lower energy is used to form volatile memory. Thus, a single memory device, formed on a single substrate, may include both nonvolatile and volatile portions. In accordance with a further aspect of this embodiment, the relative volatility of one or more portions of the memory may be altered at any time by changing an amount of energy supplied to a portion of the memory during a write process.

In accordance with yet another embodiment of the invention, pulse mode programming is used to read and write information. In this case, information can be retrieved from the device using a destructive read or a destructive write process.

In accordance with yet another embodiment of the invention, a programmable structure includes an additional electrode for sensing a state (0 or 1) of the programmable device.

### BRIEF DESCRIPTION OF THE DRAWINGS

A more complete understanding of the present invention may be derived by referring to the detailed description and claims, considered in connection with the figures, wherein like reference numbers refer to similar elements throughout the figures, and:

FIGS. 1 and 2 are cross-sectional illustrations of a programmable structure formed on a surface of a substrate in accordance with the present invention;

FIG. 3 is a cross-sectional illustration of a programmable structure in accordance with another embodiment of the present invention, illustrating phase-separated ion conductors;

FIGS. 4, 8, 9 are current-voltage diagrams illustrating current and voltage characteristics of the devices of the present invention;

FIG. 5 illustrates a current-voltage curve for a test device in accordance with the present invention; and

FIGS. 6 and 7 illustrate memory arrays in accordance with the present invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

The present invention generally relates to programmable microelectronic devices, to arrays including the devices, and to methods of forming and using the devices and arrays.

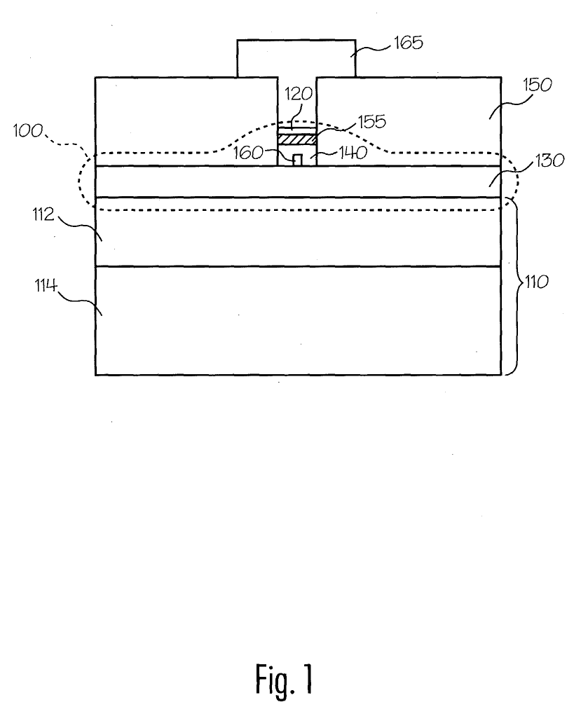

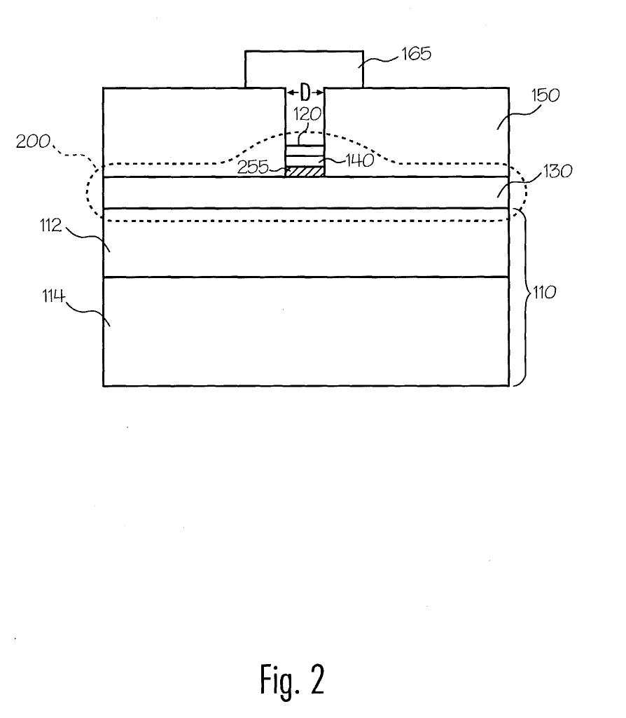

FIGS. 1 and 2 illustrate programmable microelectronic structures 100 and 200 formed on a surface of a substrate 110 in accordance with exemplary embodiments of the present invention. Structures 100 and 200 include electrodes 120 and 130, an ion conductor 140, and optionally include buffer or barrier layers or regions 155 and/or 255.

Generally, structures 100 and 200 are configured such that when a bias greater than a threshold voltage (V_{T}), discussed in more detail below, is applied across electrodes 120 and 130, the electrical properties of structure 100 change. For example, in accordance with one embodiment of the invention, as a voltage V≧V_{T} is applied across electrodes 120 and 130, conductive ions within ion conductor 140 begin to migrate and form a region 160 having an increased conductivity compared to the bulk ion conductor (e.g., an electrodeposit) at or near the more negative of electrodes 120 and 130. The amount of metal deposited depends on the magnitude and duration of the ion current, i.e., the total Faradic charge. The electrodeposit is electrically neutral and is stable in that it generally does not spontaneously leak. As region 160 forms, the resistance between electrodes 120 and 130 decreases, and other electrical properties may also change.

In the absence of any barriers, which are discussed in more detail below, the threshold voltage required to grow region 160 from one electrode toward the other, and thereby significantly reduce the resistance of the device, is approximately a few hundred millivolts. If the same voltage is applied in reverse, region 160 will dissolve back into the ion conductor and the device will return to a high resistance state. The reverse ion current will flow until the previously electrodeposited material has been oxidized and deposited back on the electrode which originally supplied the metal.

In a similar fashion, an effective barrier height of a diode that forms between an ion conductor and an electrode can be reduced by growing region 160; thus current flow may be increased through the structure, even if the resistance of the structure is substantially the same. Also, a contact resistance at the cathode can be altered by applying an adequate bias across electrodes 120, 130.

Structures 100 and 200 may be used to store information and thus may be used in memory circuits. For example, structure 100 or other programmable structures in accordance with the present invention may suitably be used in memory devices to replace FLASH, DRAM, SRAM, PROM, EPROM, EEPROM devices, or any combination of such memory. In addition, programmable structures of the present invention may be used for other applications where programming or changing of electrical properties of a portion of an electrical circuit is desired.

In accordance with various embodiments of the invention, the volatility of programmable memory (e.g., cell 100 or 200) can be manipulated by altering an amount of energy (e.g., altering time, current, voltage, thermal energy, and/or the like) applied during a write process. In the case where region 160 forms during a write process, the greater the amount of energy (having a voltage greater than the threshold voltage for the write process) applied during the write process, the greater the growth of region 160 and hence the less volatile the memory. Conversely, relatively volatile, easily erased memory can be formed by supplying relatively little energy to the cell. Thus, relatively volatile memory can be formed using the same or similar structures used to form nonvolatile memory, and less energy can be used to form the volatile/easily erased memory. Use of less energy is particularly desirable in portable electronic devices that depend on stored energy for operation. The volatile and nonvolatile memory may be formed on the same substrate and partitioned or separated from each other such that each partition is dedicated to either volatile or nonvolatile memory; or, an array of memory cells may be configured as volatile or nonvolatile memory using programming techniques, such that the configuration (i.e., volatile or nonvolatile) of the memory can be altered by changing an amount of energy supplied during programming the respective portions of the memory array.

Referring again to FIGS. 1 and 2, substrate 110 may include any suitable material. For example, substrate 110 may include semiconductive, conductive, semiinsulative, insulative material, or any combination of such materials. In accordance with one embodiment of the invention, substrate 110 includes an insulating material 112 and a portion 114 including a microelectronic devices formed using a portion of the substrate. Layer 112 and portion 114 may be separated by additional layers (not shown) such as, for example, layers typically used to form integrated circuits, including suitable barrier layers configured to mitigate unwanted diffusion of materials. Because the programmable structures can be formed over insulating or other materials, the programmable structures of the present invention are particularly well suited for applications where substrate (e.g., semiconductor material) space is a premium. In addition, forming a memory cell overlying a microelectronic device may be advantageous because such a configuration allows greater data transfer between an array of memory cells and the microelectronic device using, for example, conductive plugs formed within layers 112 and 150.

Electrodes 120 and 130 may be formed of any suitable conductive material. For example, electrodes 120 and 130 may be formed of doped polysilicon material or metal.

In accordance with one exemplary embodiment of the invention, one of electrodes 120 and 130 is formed of a material including a metal that dissolves in ion conductor 140 when a sufficient bias (V≧V_{T}) is applied across the electrodes (an oxidizable electrode) and the other electrode is relatively inert and does not dissolve during operation of the programmable device (an indifferent electrode). For example, electrode 120 may be an anode during a write process and be comprised of a material including silver that dissolves in ion conductor 140 and electrode 130 may be a cathode during the write process and be comprised of an inert material such as tungsten, nickel, molybdenum, platinum, metal silicides, conducting oxides, nitrides, and the like. Having at least one electrode formed of a material including a metal which dissolves in ion conductor 140 facilitates maintaining a desired dissolved metal concentration within ion conductor 140, which in turn facilitates rapid and stable region 160 formation within ion conductor 140 or other electrical property change during use of structure 100 and/or 200. Furthermore, use of an inert material for the other electrode (cathode during a write operation) facilitates electrodissolution of any region 160 that may have formed and/or return of the programmable device to an erased state after application of a sufficient voltage. The indifferent electrode may also be formed of a material, such as TiN, that mitigates undesired diffusion of material. In this case, a contact resistance between the ion conductor and the indifferent electrode may be relatively high, so a conducting layer—e.g., of Cr—Au may be deposited over the diffusion-barrier indifferent electrode to reduce the contact resistance. Alternatively, the structure may include a layer of barrier material underlying the indifferent electrode material, such that the indifferent electrode is interposed between the barrier material and the ion conductor material.

During an erase operation, dissolution of any region 160 that may have formed preferably begins at or near the oxidizable electrode/region 160 interface. Initial dissolution of the region 160 at the oxidizable electrode/region 160 interface may be facilitated by forming structure 100 such that the resistance at the oxidizable electrode/region 160 interface is greater than the resistance at any other point along region 160, particularly, the interface between region 160 and the indifferent electrode.

One way to achieve relatively low resistance at the indifferent electrode is to form the electrode of relatively inert, non-oxidizing material such as platinum. Use of such material reduces formation of oxides at the interface between ion conductor 140 and the indifferent electrode as well as the formation of compounds or mixtures of the electrode material and ion conductor 140 material, which typically have a higher resistance than ion conductor 140 or the electrode material.

Relatively low resistance at the indifferent electrode may also be obtained by forming a barrier layer between the oxidizable electrode (anode during a write operation) and the ion conductor, wherein the barrier layer is formed of material having a relatively high resistance. Exemplary high resistance materials are discussed in more detail below.

Reliable growth and dissolution of region 160 can also be facilitated by providing a roughened indifferent electrode surface (e.g., a root mean square roughness of greater than about 1 nm) at the electrode/ion conductor interface. The roughened surface may be formed by manipulating film deposition parameters and/or by etching a portion of one of the electrode or ion conductor surfaces. During a write operation, relatively high electrical fields form about the spikes or peaks of the roughened surface, and thus regions 160 are more likely to form about the spikes or peaks. As a result, more reliable and uniform changes in electrical properties for an applied voltage across electrodes 120 and 130 may be obtained by providing a roughed interface between the indifferent electrode (cathode during a write operation) and ion conductor 140.

Oxidizable electrode material may have a tendency to thermally dissolve or diffuse into ion conductor 140, particularly during fabrication and/or operation of structure 100. The thermal diffusion is undesired because it may reduce the resistance of structure 100 and thus reduce the change of an electrical property during use of structure 100.

To reduce undesired diffusion of oxidizable electrode material into ion conductor 140 and in accordance with another embodiment of the invention, the oxidizable electrode includes a metal intercalated in a transition metal sulfide or selenide material such as Aₓ(MB₂)₁₋ₓ, where A is Ag or Cu, B is S or Se, M is a transition metal such as Ta, V, and Ti, and x ranges from about 0.1 to about 0.7. The intercalated material mitigates undesired thermal diffusion of the metal (Ag or Cu) into the ion conductor material, while allowing the metal to participate in region 160 growth upon application of a sufficient voltage across electrodes 120 and 130. For example, when silver is intercalated into a TaS₂ film, the TaS₂ film can include up to about 67 atomic percent silver. The Aₓ(MB₂)₁₋ₓ material is preferably amorphous to prevent undesired diffusion of the metal though the material. The amorphous material may be formed by, for example, physical vapor deposition of a target material comprising Aₓ(MB₂)₁₋ₓ.

α-AgI is another suitable material for the oxidizable electrode. Similar to the Aₓ(MB₂)₁₋ₓ material discussed above, α-AgI can serve as a source of Ag during operation of structure 100—e.g., upon application of a sufficient bias, but the silver in the AgI material does not readily thermally diffuse into ion conductor 140. AgI has a relatively low activation energy for conduction of electricity and does not require doping to achieve relatively high conductivity. When the oxidizable electrode is formed of AgI, depletion of silver in the AgI layer may arise during operation of structure 100, unless excess silver is provided to the electrode. One way to provide the excess silver is to form a silver layer adjacent the AgI layer. When interposed between a layer of silver and ion conductor 140, the AgI layer reduces thermal diffusion of Ag into ion conductor 140, but does not significantly affect conduction of Ag during operation of structure 100. In addition, use of AgI increases the operational efficiency of structure 100 because the AgI mitigates non-Faradaic conduction (conduction of electrons that do not participate in the electrochemical reaction).

In accordance with one embodiment of the invention, at least one electrode 120 and 130 is formed of material suitable for use as an interconnect metal. For example, electrode 130 may form part of an interconnect structure within a semiconductor integrated circuit. In accordance with one aspect of this embodiment, electrode 130 is formed of a material that is substantially insoluble in material comprising ion conductor 140. Exemplary materials suitable for both interconnect and electrode 130 material include metals and compounds including tungsten, nickel, molybdenum, platinum, metal silicides, and the like.

As noted above, programmable structures of the present invention may include one or more barrier or buffer layers 155, 255 interposed between at least a portion of ion conductor 140 and one of the electrodes 120, 130. Layers 155, 255 may include ion conductors such as AgₓO, AgₓS, AgₓSe, AgₓTe, where x≧2, Ag_{y}I, where y≧1, CuI₂, CuO, CuS, CuSe, CuTe, GeO₂, Ge_{z}S_{1-z}, Ge_{z}Se_{1-z}, Ge_{z}Te_{1-z}, As_{z}S_{1-z}, As_{z}Se_{1-z}, As_{z}Te_{1-z}, where z is greater than or equal to about 0.1, SiOₓ, and combinations of these materials) interposed between ion conductor 140 and a metal layer such as silver.

Other materials suitable for buffer layers 155 and/or 255 include GeO₂. Amorphous GeO₂ is relatively porous an will “soak up” silver during operation of device 100, but will retard the thermal diffusion of silver to ion conductor 140, compared to structures or devices that do not include a buffer layer. When ion conductor 140 includes germanium, GeO₂ may be formed by exposing ion conductor 140 to an oxidizing environment at a temperature of about 300° C. to about 800° C. or by exposing ion conductor 140 to an oxidizing environment in the presence of radiation having an energy greater than the band gap of the ion conductor material. The GeO₂ may also be deposited using physical vapor deposition (from a GeO₂ target) or chemical vapor deposition (from GeH₄ and an O₂).

Buffer layers can also be used to increase the off resistance and “write voltage” by placing a high-resistance buffer layer (e.g., GeO₂, SiOₓ, air, a vacuum, or the like) between ion conductor 140 and the indifferent electrode. In this case, the high-resistance buffer material allows metal such as silver to diffuse through or plate across the buffer and take part in the electrochemical reaction.

When the barrier layer between the indifferent electrode and the ion conductor includes a high resistance material, the barrier may include ions that contribute to electrodeposit growth or the barrier may be devoid of ions. In either case, the barrier must be able to transmit electrons, by conduction or tunneling, such that the redox reaction occurs, allowing for region 160 growth.

In some cases, an electrodeposit may form within the high-resistance barrier layer. Exemplary high-resistance barrier layers that support electrodeposit growth include gas-filled or vacuum gap regions, porous oxide films, of other high-resistance glassy materials, and semiconductor material as long as the barrier is thin enough to allow electron tunneling from the cathode to the ion conductor at reasonable voltages (e.g., less than or equal to about 1 volt), can support electron transport, and can allow ions to be reduced within the barrier material volume.

Layers 155 and/or 255 may also include a material that restricts migration of ions between conductor 140 and the electrodes. In accordance with exemplary embodiments of the invention, a barrier layer includes conducting material such as titanium nitride, titanium tungsten, a combination thereof, or the like. The barrier may be electrically indifferent, i.e., it allows conduction of electrons through structure 100 or 200, but it does not itself contribute ions to conduction through structure 200. An electrically indifferent barrier may reduce undesired electrodeposit growth during operation of the programmable device, and thus may facilitate an “erase” or dissolution of region 160 when a bias is applied which is opposite to that used to grow region 160. In addition, use of a conducting barrier allows for the “indifferent” electrode to be formed of oxidizable material because the barrier prevents diffusion of the electrode material to the ion conductor.

Ion conductor 140 is formed of material that conducts ions upon application of a sufficient voltage. Suitable materials for ion conductor 140 include polymeric materials, glasses and semiconductor materials. In general, ion conductors in accordance with the present invention can conduct ions without requiring a phase change, can conduct ions at a relatively low temperature (e.g., below 125° C.), can conduct ions at relatively low electrical currents, have a relatively high transport number, and exhibit relatively high ion conductivity. In one exemplary embodiment of the invention, ion conductor 140 is formed of chalcogenide material (e.g., AsₓS₁₋ₓ, AsₓSe₁₋ₓ, AsₓTe₁₋ₓ, GeₓSe₁₋ₓ, GeₓS₁₋ₓ, GeₓTe₁₋ₓ, and MOₓ, where M is a transition metal). However, other materials may be used as an ion conductor in accordance with various embodiments of the invention. For example, polymeric ion conductors such as poly(ethylene oxide) may be used in accordance with the present invention.

Ion conductor 140 may also suitably include dissolved conductive material. For example, ion conductor 140 may comprise a solid solution that includes dissolved metals and/or metal ions. In accordance with one exemplary embodiment of the invention, conductor 140 includes metal and/or metal ions dissolved in chalcogenide glass. An exemplary chalcogenide glass with dissolved metal in accordance with the present invention includes a solid solution of AsₓS₁₋ₓ—Ag, AsₓSe₁₋ₓ—Ag, AsₓTe₁₋ₓ—Ag, GeₓSe₁₋ₓ—Ag, GeₓS₁₋ₓ—Ag, GeₓTe₁₋ₓ—Ag, AsₓS₁₋ₓ—Cu, AsₓSe₁₋ₓ—Cu, AsₓTe₁₋ₓ—Cu, GeₓSe₁₋ₓ—Cu, GeₓS₁₋ₓ—Cu, and GeₓTe₁₋ₓ—Cu where x ranges from about 0.1 to about 0.5, other chalcogenide materials including silver, copper, combinations of these materials, and the like. In addition, conductor 140 may include network modifiers that affect mobility of ions through conductor 140. For example, materials such as metals (e.g., silver), halogens, halides, or hydrogen may be added to conductor 140 to enhance ion mobility and thus increase erase/write speeds of the structure. Furthermore, as discussed in more detail below, ion conductor 140 may include a plurality of regions having different resistance values—for example, ion conductor 140 may include a first region proximate the oxidizable electrode having a relatively low resistance and a second region proximate the indifferent electrode having a relatively high resistance.

To increase the thermal stability of ion conductor, doped oxides and/or oxide-doped chalcogenides are used as ion conductor 140. Exemplary oxide dopants for chalcogenide materials include oxygen, GeO₂, As₂O₃, Ag₂O, Cu(_{1,2})O, and SiO₂ and exemplary oxides suitable for doping include silver or copper doped GeO₂, As₂O₃, Ag₂O, Cu(_{1,2})O, WOₓ and other transition metal oxides and SiOₓ. In the case of doped oxides, ion conductor 140 is preferably less than about 10 nm thick.

Ion conductor 140 may also include a filler material, which fills interstices or voids. Suitable filler materials include non-oxidizable and non-silver based materials such as a non-conducting, immiscible silicon oxide and/or silicon nitride, having a cross-sectional dimension of less than about 1 nm, which do not contribute to the growth of region 160. In this case, the filler material is present in the ion conductor at a volume percent of up to about 5 percent to reduce a likelihood that a region 160 will spontaneously dissolve into the supporting ternary material as the device is exposed to elevated temperature, which leads to more stable device operation without compromising the performance of the device. Ion conductor 140 may also include filler material to reduce an effective cross-sectional area of the ion conductor. In this case, the concentration of the filler material, which may be the same filler material described above but having a cross-sectional dimension up to about 50 nm, is present in the ion conductor material at a concentration of up to about 50 percent by volume.

A high resistance region can be formed within the electrolyte by creating a “layered” electrolyte, in which the silver concentration is<10 at. % within a few nm of the cathode (which typically lies beneath the electrolyte), compared with>40 at. % near the anode (typically placed on top of the electrolyte). Such a layered electrolyte increases the off resistance of the structure and reduces unwanted “blanket” plating of silver on the cathode during forward biasing, thereby improving device characteristics (see later). We typically use this type of electrolyte structure in our devices.

Layering the ion conductor increases the endurance (the number of write-erase cycles a device is capable of withstanding without failure) of programmable structures in accordance with various embodiments of the invention. Endurance is a critical factor for SRAM and DRAM-like applications. Since the operational electric fields are more than an order of magnitude below breakdown levels of the structures described herein, the electrolyte is stable under field stressing so this does not appear to limit endurance. However, even though the devices cannot be over erased, they can be over-written. Excessive write operations, particularly if the metal concentration in the electrolyte near the cathode is high, will result in the inert cathode becoming “plated” with silver so that the device will form an electrodeposit for both forward and reverse bias. This creates a “stuck bit” situation and limits the endurance. In addition, contaminants in the electrolyte can also limit endurance by taking part in unwanted electrochemical reactions. A good example of this is free oxygen, which will form resistive oxide layers at the electrodes during cycling, which will limit both electrodeposition and electrodeposit removal. However, the use of a layered electrolyte and the application of erase pulses that are longer than the write pulses (e.g., by 50% or more) help to ensure that the plating of the write cathode is significantly reduced. In addition, the use of materials preparation and processing techniques that minimize the presence of oxygen and other contaminants will decrease the electrode oxidation effect. Over 10¹¹ 400 nsec write/600 nsec erase cycles with 200 nsec pulse spacing at a programming current of about 10 μA were applied to micron-scale Ag—Ge—Se devices with a layered electrolyte, which contain less than 1 at. % oxygen without substantial electrolyte or electrode damage. Enhanced endurance can be achieved as well as by formation of electrolyte films with column structure or template structure that could limit the lateral ion diffusion and could contribute towards increased switching speed.

Referring again to FIGS. 1 and 2, in accordance with one exemplary embodiment of the invention, ion conductor 140 includes a germanium-selenide glass with silver diffused in the glass. Germanium selenide materials are typically formed from selenium and Ge(Se)_{4/2} tetrahedra that may combine in a variety of ways. In a Se-rich region, Ge is 4-fold coordinated and Se is 2-fold coordinated, which means that a glass composition near Ge_{0.20}Se_{0.80} will have a mean coordination number of about 2.4. Glass with this coordination number is considered by constraint counting theory to be optimally constrained and hence very stable with respect to devitrification. The network in such a glass is known to self-organize and become stress-free, making it easy for any additive, e.g., silver, to finely disperse and form a phase separated glass. Accordingly, in accordance with one embodiment of the invention, ion conductor 140 includes a glass having a composition of Ge_{0.17}Se_{0.83} to Ge_{0.25}Se_{0.75}; this is the composition of the “backbone” glass, after the metal has diffused through the glass.

When conductive material such as metal is added to an ion conductor material, phase-separated regions of the metal-doped ion conductor may form. In this case, a macroscopic view of the doped ion conductor may appear glassy even though small, phases-separated regions are formed.

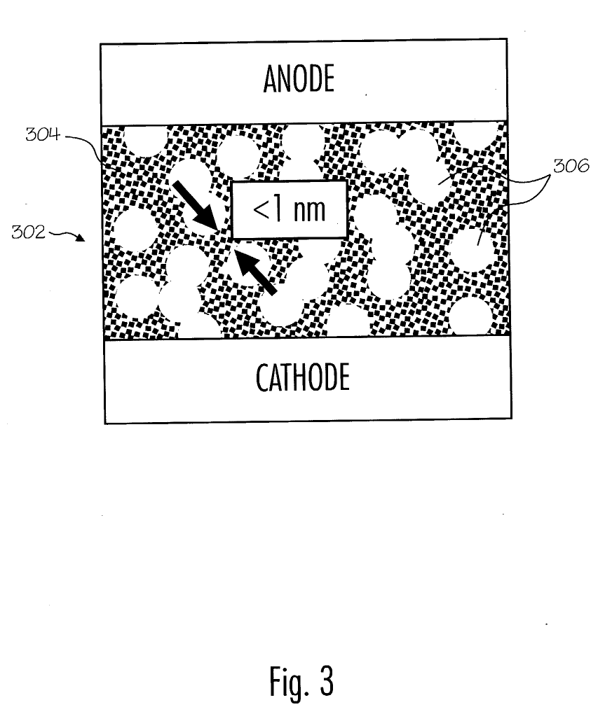

FIG. 3 illustrates portions of programmable structures, which include a phase-separated ion conductor region 302, including a high-resistance portion 304 and low-resistance portions 306, in accordance with various embodiments of the present invention. By way of particular example, ion conductor 302 includes silver doped GeₓSe₁₋ₓ, where x is less than about 0.33 and preferably ranges from about 0.17 to about 0.3 and more preferably has a value of about 0.17 to about 0.25. In this case, an electrolyte formed by silver dissolution into a thin film of chalcogen-rich glass includes a finely dispersed low resistivity silver-rich phase around 2 nm in average diameter and an interstitial germanium-rich glassy phase that exhibits a high resistivity. The resistivities are about 2 mΩ.cm and 70 mΩ.cm for the selenide and sulfide silver-rich phases respectively and is estimated to be about 10⁵ to 10⁶ Ω.cm for the germanium-rich phases. For a silver-saturated ternary, the glassy interstices between the silver-rich regions have an average width of less than about 1 nm but the material's high resistivity makes the electrolyte resistance relatively high, on the order of 10² Ω.cm for the selenide-based electrolyte and on the order of 10³ Ω.cm for the sulfide-based material with the same silver content.

The ion current in the electrolyte takes the form of a coordinated motion of ions—all mobile silver in the current path from the anode to the cathode takes part in the current flow and moves in a sequential fashion. At the nanoscale level, each silver-rich region in the current path acts as a local supply of ions. For each excess ion that enters one of these regions from the anode side, one will simultaneously leave on the cathode side and move into the interstitial zone there. Once in this glassy material, the high local electric field will cause the ions to move toward the adjacent downstream silver-rich region. The electron current from the cathode will also flow into the electrolyte and the supply of both ions and electrons in the interstitial zones results in electrodeposition so the excess metal in the electrolyte is effectively “stored” in these nanoscale regions. The conductive electrodeposits bridge the interstitial regions and help supply electrons to regions further away from the cathode until the bridging to the anode is complete.

It is thought that phase-separated ion conductors facilitate large off resistance and high switching speed of programmable devices such as device 100. The reason for this is that the metal ions from the soluble electrode will migrate within region 304 to bridge low-resistance regions 306. Reduction of metal ions preferentially occurs in high-resistance regions 304 because the local field is highest in this area of ion conductor 302. This process is relatively fast because a typical gap between low-resistance portions is on the order of about 1 nm or less. Additional phase-separated structures are discussed in application Ser. No. 10/390,268, entitled PROGRAMMABLE STRUCTURE, AN ARRAY INCLUDING THE STRUCTURE, AND METHODS OF FORMING THE SAME, filed Mar. 17, 2003, the contents of which are hereby incorporated herein by reference.

Other exemplary materials suitable for phase-separated ion-conductor material include silver and/or copper-doped germanium chalcogenides (e.g., sulfides and tellurides) and mixtures of these compounds, silver and/or copper-doped arsenic chalcogenides (e.g., selenides, sulfides, and tellurides) and mixtures of these compounds. Other exemplary phase-separate ion conductors include Ag₂Se dispersed within AgI or within an ion conductive polymer such as poly(ethylene oxide) and additional exemplary low-resistance material suitable for portion 304 include SiOₓ, GeO₂, and Ag₂O. It should be noted, however, that any ion conductor material that includes a low-resistance phase dispersed within a low-resistance phase will function in accordance with the present invention as described herein.

Referring again to FIGS. 1 and 2, in accordance with one exemplary embodiment of the invention, at least a portion of structure 100 is formed within a via of an insulating material 150. Forming a portion of structure 100 within a via of an insulating material 150 may be desirable because, among other reasons, such formation allows relatively small structures, e.g., on the order of 10 nanometers, to be formed. In addition, insulating material 150 facilitates isolating various structures 100 from other electrical components. In accordance with various embodiments of the invention, the via may be lined with one or more of the barrier materials described herein to reduce unwanted diffusion and/or reduce an active area size of the programmable structure.

Insulating material 150 suitably includes material that prevents undesired diffusion of electrons and/or ions from structure 100. In accordance with one embodiment of the invention, material 150 includes silicon nitride, silicon oxynitride, polymeric materials such as polyimide or parylene, or any combination thereof.

A contact 165 may suitably be electrically coupled to one or more electrodes 120, 130 to facilitate forming electrical contact to the respective electrode. Contact 165 may be formed of any conductive material and is preferably formed of a metal, alloy, or composition including aluminum, tungsten, or copper.

In accordance with one embodiment of the invention, structure 100 is formed by forming electrode 130 on substrate 110. Electrode 130 may be formed using any suitable method such as, for example, depositing a layer of electrode 130 material, patterning the electrode material, and etching the material to form electrode 130.

Insulating layer 150 may be formed by depositing insulating material onto electrode 130 and substrate 110 and forming vias in the insulating material using appropriate patterning and etching processes. Ion conductor 140 and electrode 120 may then be formed within insulating layer 150 by depositing ion conductor 140 material and electrode 120 material within the via. Such ion conductor and electrode material deposition may be selective—i.e., the material is substantially deposited only within the via, or the deposition processes may be relatively non-selective. If one or more non-selective deposition methods are used, any excess material remaining on a surface of insulating layer 150 may be removed using, for example, chemical mechanical polishing and/or etching techniques. Barrier layers 155 and/or 255 may similarly be formed using any suitable deposition and/or etch processes.

A solid solution suitable for use as ion conductor 140 may be formed in a variety of ways. For example, the solid solution may be formed by depositing a layer of conductive material such as metal over a chalcogenide glass without breaking a vacuum and exposing the metal and glass to thermal and/or photo dissolution processing. In accordance with one exemplary embodiment of the invention, a solid solution of As₂S₃—Ag is formed by depositing As₂S₃ onto a substrate, depositing a thin film of Ag onto the As₂S₃, and exposing the films to light having energy greater than the optical gap of the As₂S₃,—e.g., light having a wavelength of less than about 500 nanometers (e.g., light having a wavelength of about 436 nm at about 6.5 mW/cm²). With this process the chalcogenide glass can incorporate over 30 atomic percent of silver and remain macroscopically glassy and microscopically phase separated. If desired, network modifiers may be added to conductor 140 during deposition of conductor 140 (e.g., the modifier is in the deposited material or present during conductor 140 material deposition) or after conductor 140 material is deposited (e.g., by exposing conductor 140 to an atmosphere including the network modifier).

In accordance with another embodiment of the invention, a solid solution may be formed by depositing one of the constituents from a source onto a substrate or another material layer and reacting the first constituent with a second constituent. For example, germanium (preferably amorphous) may be deposited onto a portion of a substrate and the germanium may be reacted with H₂Se to form a Ge—Se amorphous film. Similarly, arsenic can be deposited and reacted with the H₂Se gas, or arsenic or germanium can be deposited and reacted with H₂S gas. Silver or other metal can then be added to the material as described above.

When used, oxides may be added to the ion conductor material by adding an oxide to a melt used to form a chalcogenide ion conductor source. For example, GeO₂, As₂O₃, Ag₂O, Cu(_{1,2})O, and SiO₂, can be added to GeₓS₁₋ₓ, AsₓS₁₋ₓ, GeₓSe₁₋ₓ, AsₓSe₁₋ₓ, GeₓTe₁₋ₓ, AsₓTe₁₋ₓ to form an oxide-chalcogenide glass including up to several tens of atomic percent oxygen. The ternary or quaternary glass can then be used to deposit a film of similar composition on the device substrate by physical vapor deposition or similar technique. Alternatively, the oxygen-containing film may be formed in-situ using reactive deposition techniques in which the chalcogenide material is deposited in a reactive oxygen ambient to form an ion conductor including up to several tens of atomic percent of bound oxygen. Conductive material such as silver or copper can be incorporated into the source glass melt or introduced into the deposited film by thermal or photo-dissolution as discussed above.

Similarly, metal doped oxides may be deposited from a synthesized source which contains all the necessary elements in the correct proportions (e.g., AgₓO (x>2), CuₓO (x>2), Ag/Cu—GeO₂, Ag/Cu—As₂O₃, or Ag/Cu—SiO₂) or the silver or copper may be introduced into the binary oxide film (Ag₂O, Cu(_{1,2})O, GeO₂, As₂O₃, or SiO₂) by thermal- or photo-dissolution from a thin surface layer of the metal. Alternatively, a base layer of Ag, Cu, Ge, As, or Si may be deposited first and then reacted with oxygen to form the appropriate oxide and then diffused with Ag or Cu as discussed above. The oxygen reaction could be purely thermal or plasma-assisted, the latter producing a more porous oxide.

One of the electrodes may be formed during ion conductor 140 doping by depositing sufficient metal onto an ion conductor material and applying sufficient electrical or thermal energy to the layers such that a portion of the metal is dissolved within the ion conductor material and a portion of the metal remains on a surface of the ion conductor to form an electrode (e.g., electrode 120). Regions of differing conductivity within ion conductor 140 can be formed using this technique by applying a sufficient amount of energy to the structure such that a first portion of the ion conductor proximate the soluble electrode contains a greater amount of conductive material than a second portion of the ion conductor proximate the indifferent electrode. This process is self limiting if ion starting ion conductor layer is thick enough so that a portion of the film becomes saturated and a portion of the film is unsaturated.

In accordance with alternative embodiments of the invention, solid solutions containing dissolved metals may be directly deposited onto substrate 110 and the electrode then formed overlying the ion conductor. For example, a source including both chalcogenide glass and conductive material can be used to form ion conductor 140 using physical vapor deposition or similar techniques.

An amount of conductive material such as metal dissolved in an ion conducting material such as chalcogenide may depend on several factors such as an amount of metal available for dissolution and an amount of energy applied during the dissolution process. However, when a sufficient amount of metal and energy are available for dissolution in chalcogenide material using photodissolution, the dissolution process is thought to be self limiting, substantially halting when the metal cations have been reduced to their lowest oxidation state. In the case of As₂S₃—Ag, this occurs at Ag₄As₂S₃=2Ag₂S+As₂S, having a silver concentration of about 47 atomic percent. If, on the other hand, the metal is dissolved in the chalcogenide material using thermal dissolution, a higher atomic percentage of metal in the solid solution may be obtained, provided a sufficient amount of metal is available for dissolution.

In accordance with a further embodiment of the invention, the solid solution is formed by photodissolution to form a macrohomogeneous ternary compound and additional metal is added to the solution using thermal diffusion (e.g., in an inert environment at a temperature of about 85° C. to about 150° C.) to form a solid solution containing, for example, about 30 to about 50, and preferably about 34 atomic percent silver. Ion conductors having a metal concentration above the photodissolution solubility level facilitates formation of regions 160 that are thermally stable at operating temperatures (typically about 85° C. to about 150° C.) of devices 100 and 200.

Alternatively, the solid solution may be formed by thermally dissolving the metal into the ion conductor at the temperature noted above; however, solid solutions formed exclusively from photodissolution are thought to be less homogeneous than films having similar metal concentrations formed using photodissolution and thermal dissolution.

Information may be stored using programmable structures of the present invention by manipulating one or more electrical properties of the structures. For example, a resistance of a structure may be changed from a “0” or off state to a “1” or on state during a suitable write operation. Similarly, the device may be changed from a “1” state to a “0” state during an erase operation.

Write, Read, and Erase Processes

A typical PMC memory structure can be modeled as a small geometry conductor/solid electrolyte/oxidizable electrode stack in which the small-signal off characteristics are governed by electrode polarization (double layer) effects as well as the electrolyte resistivity. These combine to yield an exponential I-V characteristic, not unlike a forward biased Schottky junction, in the off-state device. For a uniformly silver saturated germanium selenide film, the highest resistance (at about 50 mV where maximum polarization occurs) is in the order of about 10⁵ Ω.μm², dropping to about 0.15 times this value just below the write threshold. In a layered selenide or sulfide electrolyte which has a reduced silver content at the cathode, the maximum effective resistance through the film can be in excess of about 10⁸ Ω.μm² and about 0.1-0.2 times this value at the write threshold. There is also a small capacitance associated with polarization in the off state, on the order of about 10 fF/μm². The off state resistance rises and the capacitance falls with decreasing device area as they are defined by device geometry, properties which are highly desirable for device scaling.

The electrodeposition effect in the glassy interstitial material greatly reduces its resistivity. Since the electrolyte resistance is dominated by the interstitial material, its reduced resistivity results in a profound reduction in the overall resistance of the film. The on characteristics of the PMC memory are therefore determined by the “strength” of the electrodeposited links—the more reduced silver in the linking regions, the lower the effective film resistance and the resistivity of the dispersed conducting regions they connect together. In addition, the on resistance is a simple function of the applied current limit since electrodeposition only proceeds if the voltage across the device is in excess of 300 mV, the typical “write threshold” for sulfide- or selenide-based devices. When a forward bias in excess of the write threshold is applied to the off device, the resistance decreases and the current rises to the set limit. However, once the resistance falls to the point at which the voltage drop is below the write threshold, the electrodeposition halts and the resistance is then fixed. This effect may be expressed simply as

Rₒₙ=V_{w}/I_{prog}

where Rₒₙ is the on resistance, V_{w} is the electrodeposition threshold, and I_{prog} is the maximum programming current. For example, a current limit of 10 μA will result in an on state resistance of 30 kΩ for a write threshold of 300 mV, which is many orders of magnitude lower than a typical off state. Note that whereas the off state resistance increases with decreasing device area, the mechanism governing on resistance is independent of device size and this is also good for scaling. If a reverse bias in excess of approximately 300 mV is applied, the electrodeposit silver is oxidized to disperse the conducting link and the silver is replaced on the oxidizable electrode (now the cathode). This reverse reaction is self-limiting and terminates when all the excess silver in the electrodeposit is oxidized so the devices cannot be over-erased.

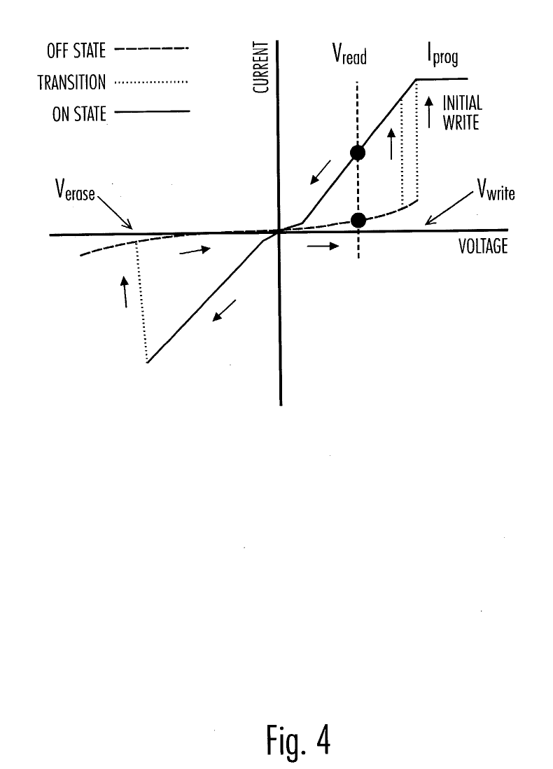

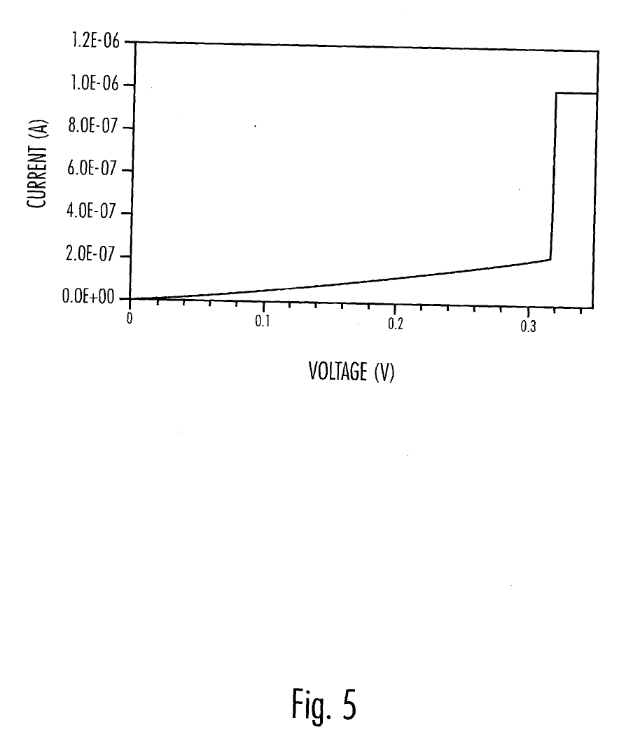

FIG. 4 shows a schematic diagram of the write and erase current-voltage characteristics of a metal-electrolyte-metal PMC device. The off state in both forward and reverse bias has a non-ohmic character due to the nature of the electrolyte and the electrode-electrolyte interfaces. The ion current only flows during the write and erase transitions and the electron current flows through the electrolyte in the off state and through the electrodeposited pathway in the on state. The on state is metallic in nature but with a slightly non-ohmic character at low voltage due to the inhomogeneous nature of the conducting pathway. The read voltage is chosen to be sufficiently less than the write voltage to avoid read disturb events. FIG. 5 is an example of a current-voltage curve for a large (8 μm) layered Ge_{0.20}S_{0.80} PMC test device, with silver anode and nickel cathode, which has been switched from 2.5 MΩ range to 320 kΩ at 320 mV for I_{prog}=1 μA. This is an initial switching event for this particular device, evident by the magnitude of the writing voltage (320 mV), which is at the high end of the typical range. Layered devices which have lower silver concentration near the cathode generally exhibit an initial write threshold which is about 20-40 mV above all subsequent write operations. This is thought to be due to a “path forming” process in the electrolyte, which occurs only during the initial writing operation. This slightly reduces the activation energy for all subsequent electrodeposition events along the same (now preferred) path. This effect is not nearly so evident in devices using uniformly saturated electrolytes, which generally tend to have much lower write thresholds (as low as 180 mV), and this suggests that the path forming process is particularly significant in the reduced silver concentration region of the layered electrolytes.

The performance of PMC devices can be predicted by considering the nanostructure of the solid electrolyte and the electrochemical reactions that occur at the nanoscale. In traversing an interstitial glass region, an ion will move less than 1 nm on average. For an applied voltage of 300 mV across a film, which is 10 nm thick, the electric field in the interstitial regions will be around 10⁵ V/cm. Since the high field ion mobility is as high as 10⁻³ cm²/V.s, the average ion transit time will be less than 1 nsec. If we assume an average single electrodeposition volume in the interstitial glass in the order of 1 nm³, the rapid ion supply will mean that each interstitial region will have silver deposited in it in 1 nsec or less and that this nanoscale electrodeposition event will consume less than 10 aC of charge. In an electrolyte film around 10 nm thick, as used in our current PMC memory devices, multiple nanoscale storage volumes will be involved and a combination of sequential and parallel electrodeposition will occur in these regions, increasing the amount of ion-reducing charge used. A single nanoscale pathway will exhibit a resistance in the MΩ range and so is insufficient to define an easily detected on state. In contrast, several hundred interstitial volumes will be involved in fully bridging the interstices in a 10 nm thick film to produce an on resistance in the 10 kΩ range but since these will mostly lie in parallel, a sub-10 nsec bridging time is still attainable for a programming current of a few tens of μA. The same reasoning can be applied in the reverse bias case to predict a sub-10 nsec erase time. As one could expect, the switching characteristics in the test device shown in FIG. 5 are dominated by parasitic capacitances (related to probe pads and interconnect) which can be as high as 2 pF. However, we have been able to demonstrate single rapid switching events in the 10 nsec regime by precharging these devices to within 50 mV of the write threshold and then applying a short pulse above this threshold.

In addition to speed, voltage, and power/energy consumption requirements, retention and endurance are factors to be considered. Retention or non-volatility in PMC devices is related to the stability of the electrodeposit. Whereas the amount of silver electrodeposited will not change with time until the device is erased, unless the device has been “hard written” to a few kΩ or less, its precise distribution within the electrolyte can be altered if the device is subjected to elevated temperatures (e.g. over 60° C.) for several days, i.e., the silver can slowly diffuse away from the electrodeposition regions which form the conducting pathway. This has the effect of increasing the on resistance of a programmed device as the decrease in the local silver concentration increases the resistivity of the interstitial glass. However, since the electrolyte remains supersaturated following a write operation, the overpotential and activation energy for redeposition is lowered so that the device will re-write to a reduced resistance state at a lower voltage than the normal write threshold. Note that the refresh voltage for a written but “drifted” (high resistance) device is as low as 100 mV (compared to an unwritten/erased threshold of around 300 mV). This allows the data to be self-refreshed at any time by applying a sub-threshold pulse which is incapable of writing an unwritten/erased device. This technique can extend the device retention practically indefinitely. In the case of hard written devices, particularly those that have been programmed to less than 1 kΩ, the interstices are sufficiently saturated such that very little silver diffusion occurs and the resistance stays relatively constant even for several months at elevated temperature. However, hard low resistance states require writing currents in the 100s of μA, which increases the programming power and energy.

Pulse Mode Read/Write

In accordance with an alternate embodiment of the invention, pulse mode programming is used to write to and read from a programmable structure. In this case, similar to the process described above, region 160 forms during a write process; however, unlike the process described above, at least a portion region 160 is removed or dissolved during a read operation. During an erase/read process, the magnitude of the current pulse is detected to determine the state (1 or 0) of the device. If the device had not previously been written to or has previously been erased, no ion current pulse will be detected at or above the reduction/oxidation potential of the structure. But, if the device is in a written state, an elevated current will be detected during the destructive read/erase step. Because this is a destructive read operation, information must be written to each structure after each read process—similar to DRAM read/write operations. However, unlike DRAM devices, the structures of the present invention are stable enough to allow a range of values to be stored (e.g., various amounts of region 160). Thus, a partially destructive read that decreases, but does not completely eliminate region 160, can be used. In accordance with an alternate aspect of this embodiment, a destructive write process rather than a destructive erase process can be used read the device. In this case, if the cell is in an “off” state, a write pulse will produce an ion current spike as region 160 forms, whereas a device that already includes a region 160 will not produce the ion current spike if the process has been limited by a lack of oxidizable silver.

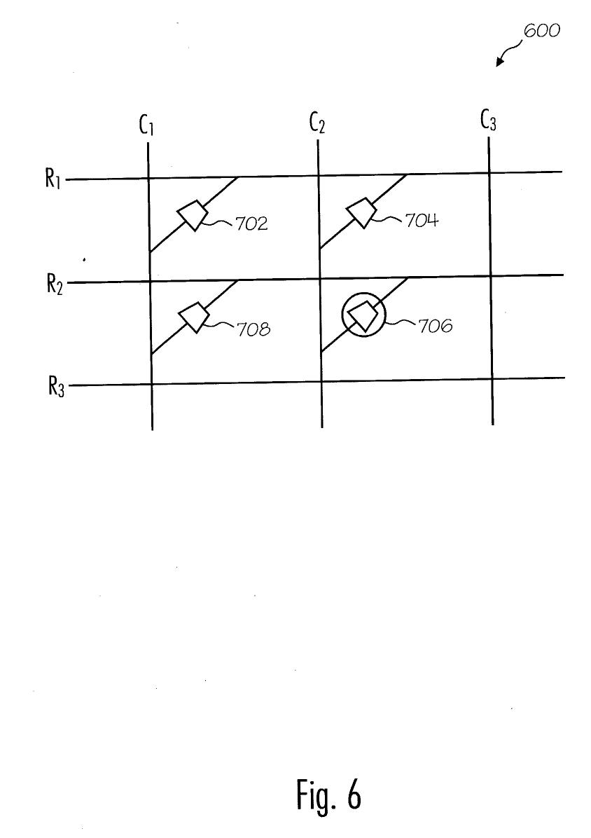

FIG. 6 illustrates an array 600 of programmable structure 702-708 that form rows R₁-R₃ and column C₁-C₃ of programmable structures. When pulse-mode programming is employed to read and write to array 600, additional diodes and transistors typically used for structure isolation, are not required, so long as regions 160 of the structures are not grown to an extent that they short the structure. A non-bridging region can be obtained by using limited write times, limiting an amount of oxidazable material at the oxidizable electrode that can contribute to region 160 formation, and/or using a resistive region between the electrodes that allows sufficient electron current, but prevents or decreases electrodeposition throughout ion conductor 140.

In array 600, a non-bridging region 160 is grown in the selected structure by, for example, biasing C₂=+Vₜ/2, R₂=−Vₜ/2, where Vₜ is the reduction/oxidation potential, with all other rows and columns held at or near zero volts, so that no other device in the array sees the full forward write voltage. The resistance remains high after writing as the electrodeposit (region 160) does not bridge the electrodes. The read/erase bias is C₂=−Vₜ/2, R₂=+Vₜ/2 with all others held at zero volts. If the device is in the off state and the erase pulse is applied, very little current will flow through the high resistance electrolyte. If, however, a partial electrodeposit has been formed by a write operation, an erase pulse will produce an ion current spike through C₂ and R₂ as the electrodeposited metal is oxidized and re-plated on the negative electrode (the oxidizable anode in the write process). This current spike can be sensed and therefore the state of the selected cell can be determined by this process. Note that it is also possible to use full rather than half or partial voltages when the non-selected rows and columns are allowed to float (via the use of tri-state drivers); e.g., C₂=+Vₜ and R₂=0 for write, C₂=0 and R₂=+Vₜ for read/erase.

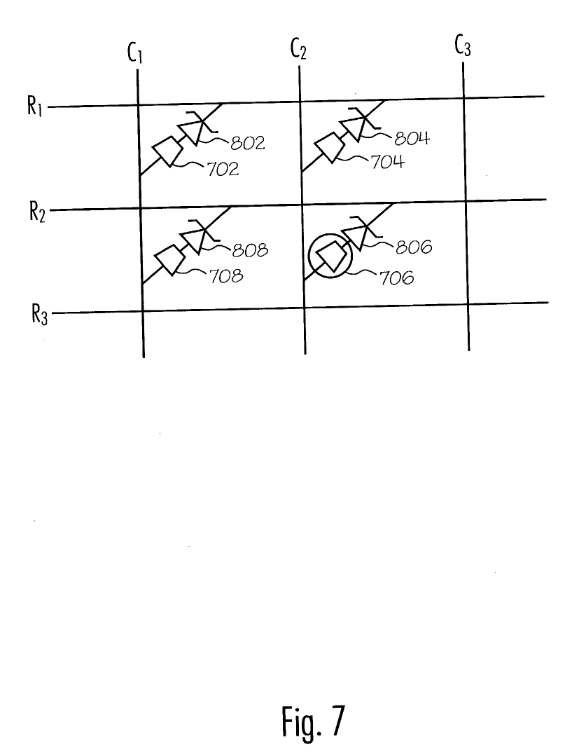

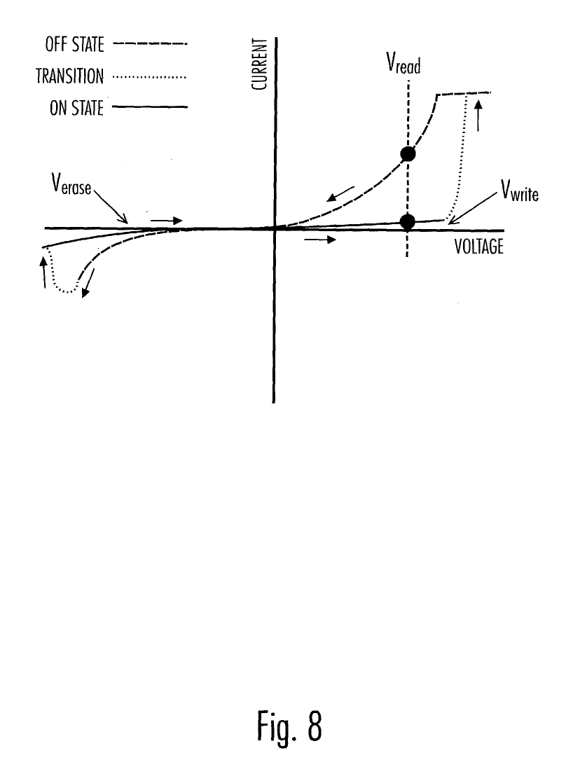

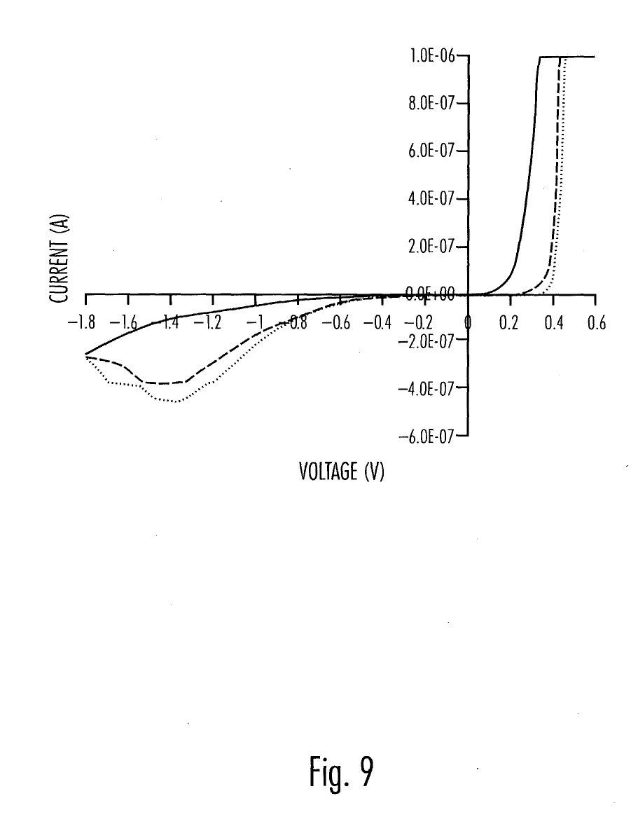

FIG. 7 schematically illustrates an array of PMC devices 702-708 coupled in series to diodes 802-808. The schematic I-V characteristic of a PMC device with a series diode is shown in FIG. 8. The forward characteristic of the diode leads to a higher write voltage but the diode's reverse high resistance blocking region will provide cell-to-cell isolation in a cross-point array. The series diodes are fabricated using highly doped n-type silicon (10¹⁸ cm⁻³ antimony) as the cathode of a 4 μm PMC device so that a rectifying junction is formed with the p-type Ag-doped chalcogenide and also with the electrodeposit in an on-state device and a multiple-cycle I-V characteristic, as shown in FIG. 9. The write threshold has been increased by around 100 mV and the effect of the path-forming process can be clearly seen as the initial write occurs at around 30 mV higher than the subsequent write operations. The off resistance is in the 10⁸ Ω range and the final on resistance for a 1 μA programming current is about 360 kΩ. In the illustrated case, the device does not fully erase until about −1.8 V, indicating an effective blocking voltage of about 1.4-1.6 V, and has a resistance in the order of 1.5×10⁸ Ω.μm² at −V_{E}/2, which is sufficient for passive array applications. The erase curve is more gradual than in a typical metal-electrolyte-metal device due to the change in relative voltage drops across the PMC element and its reverse biased series diode during the erase process. It is also somewhat erratic in this plot as the devices have actually been overwritten by the slow forward bias sweep that was used to acquire the writing curves. Note that the effective erase voltage of this structure is a function of the doping level of the silicon layer and can be made lower for higher dopant concentrations.

Arrays 600 and 700 may be formed using interference imaging techniques. In this case, light, electron beams, or other forms of energy are used to create interference patterns on energy sensitive material to patter the word and/or bit lines. This allows for nanoscale array formation with bit densities of about 10¹⁰ cells per square centimeter or more. For example, interference techniques can be used to form lines of soluble electrode material in one direction on a first layer and lines of indifferent electrode material in a direction that is orthogonal to the lines of soluble electrode material on a second layer. Programmable structures are formed by placing ion conductor material at the intersections between the lines of soluble material and the lines of indifference material (e.g., by forming the ion within a via). This technique can also be used for direct writing (without the use of photoresist) to diffuse conductive material into the ion conductor. For example, the interference technique can be used to cause conductive material (e.g., Ag) overlying an ion conductor (e.g., Ge—Se) to photodiffuse into the ion conductor only where the interference patters provide enough photonic energy for the diffusion.

Scaling and Density

As noted above, key attributes of high density solid state memory of the present invention include: (1) low internal voltage to allow the close packing of structures without breakdown and crosstalk and to reduce power supply requirements, (2) low power/energy consumption to avoid problems with power density and heating in closely-packed structures and to facilitate the use of small battery power sources in portable applications, and (3) the ability for the devices to be scaled to minimum or even sub-lithographic dimensions.

The extremely low voltage operation, combined with programming current in the order of microamps or less and sub-ten nanosecond intrinsic write/erase time means that the energy required to reduce the resistance of the device by many orders of magnitude lies near 1 fJ per cell, thereby meeting conditions 1 and 2 above. The “active-in-via” (AIV) variant of the PMC technology has the device wholly contained within a minimum geometry via in an inter-metal dielectric layer, as illustrated in FIGS. 1 and 2. Indeed, the actual via diameter and therefore the diameter of the active region of the device can easily be sub-lithographic using a conformal sidewall fill (typically a barrier dielectric such as Si₃N₄) followed by an anisotropic etch. This approach allows the metallization for the electrodes to be at the critical dimension while completely overlapping the electrolyte. This is an extremely compact structure, no larger than 4F² in area (where F is the critical dimension), and lends itself well to scaling. The fabrication of AIV devices as small as 50 nm (lateral dimension) in diameter has been achieved using electon-beam lithography and much more aggressive scaling (to below 10 nm) is possible and so condition 3 above is also met. Note that since the memory elements reside in vias between metallization levels, the technology will be compatible with CMOS processing as long as appropriate seals and barrier layers are used, similar to those employed in copper metallization processes.

To achieve maximum information storage density, the simplest layout is a cross point matrix where one metal layer forms the columns (e.g., bit lines) and the metal layer above holds the rows (word lines). The memory devices reside in the vias at each crossing point with a minimum geometry diode being used for cell isolation purposes, as illustrated in FIG. 7, to keep the cell area at 4F²—i.e., at least a portion of the diode is formed within the via. In this array, the selected cell is written by making C₂=+V_{w}/2, R₂=−V_{w}/2 with all other rows and columns held at zero volts so that no other device in the array sees the full forward write voltage. To erase the selected cell, we make C₂=−V_{E}/2, R₂=+V_{E}/2 (where V_{E} is the reverse turn-on voltage of the diode plus the erase voltage of the device) with all other rows and columns again held at zero volts. The selected device is read using much the same approach by making C₂=+V_{R}/2, R₂=−V_{R}/2 (where V_{R} is chosen to be below the write threshold) with all other rows and columns held at zero volts.

Programmable structures and devices and system including the programmable structures described herein are advantageous because the programmable structures require relatively little internal voltage to perform write and erase functions, require relatively little current to perform the write and erase functions, are relatively fast (both write and read operations), require little to no refresh (even for “volatile” memory applications), can be formed in high-density arrays, are relatively inexpensive to manufacture, are robust and shock resistant, and do not require a monocrystalline starting material and can therefore be added to other electronic circuitry.

Although the present invention is set forth herein in the context of the appended drawing figures, it should be appreciated that the invention is not limited to the specific form shown. For example, while the programmable structure is conveniently described above in connection with programmable memory devices, the invention is not so limited; the structure of the present invention may additionally or alternatively be employed as programmable active or passive devices within a microelectronic circuit. Furthermore, although only some of the devices are illustrated as including buffer, barrier, or diode components, any of these components may be added to the devices of the present invention. Various other modifications, variations, and enhancements in the design and arrangement of the method and apparatus set forth herein, may be made without departing from the spirit and scope of the present invention as set forth in the appended claims.

We claim:

1. A microelectronic programmable structure comprising:
an ion conductor comprising an electrolyte and conductive material, wherein the ion conductor includes a first region having a first conductivity and a second region having a second conductivity;
an oxidizable electrode proximate the ion conductor; and
an indifferent electrode proximate the ion conductor.

2. The microelectronic programmable structure of claim 1, wherein the ion conductor comprises a material selected from the group consisting of sulfur, selenium, and tellurium, and oxygen.

3. The microelectronic programmable structure of claim 1, wherein the ion conductor comprises a material selected from the group consisting of GeO₂, As₂O₃, Ag₂O, Cu(_{1,2})O, SiO₂, GeₓS₁₋ₓ, AsₓS₁₋ₓ, GexSe₁₋ₓ, AsₓSe₁₋ₓ, GeₓTe_{1-x, As}ₓTe₁₋ₓ, WOₓ and other transition metal oxides MOₓ, where M is a transition metal, and polymeric material.

4. The microelectronic programmable structure of claim 1, wherein the conductive material comprises a material selected from the group consisting of silver and copper.

5. The microelectronic programmable structure of claim 1, further comprising a barrier layer between the oxidizable electrode and the indifferent electrode.

6. The microelectronic programmable structure of claim 1, wherein the oxidizable electrode and the indifferent electrode are substantially coplanar.

7. The microelectronic programmable structure of claim 1, wherein the ion conductor is interposed between the indifferent electrode and the oxidizable electrode.

8. The microelectronic programmable structure of claim 1, wherein at least a portion of the structure is formed within a via in an insulating layer.

9. The microelectronic programmable structure of claim 8, wherein a width of the via is less than about 65 nm.

10. The microelectronic programmable structure of claim 8, wherein the via is lined with a barrier material.

11. The microelectronic programmable structure of claim 1, wherein the ion conductor comprises a phase-separated material.

12. The microelectronic programmable structure of claim 1, wherein the first region comprises less than about 10 atomic percent metal and the second region comprises more than about 40 atomic percent metal.

13. The microelectronic programmable structure of claim 1, wherein at least a portion of the structure is formed within a via in an insulating layer, the structure further comprising a diode.

14. The microelectronic programmable structure of claim 13, wherein at least a portion of the diode is formed within the via.

15. The microelectronic programmable structure of claim 1, further comprising a barrier layer, wherein indifferent electrode is between the barrier layer and the ion conductor.

16. The microelectronic programmable structure of claim 1, wherein the indifferent electrode comprises a barrier material and a conductive material.

17. A method of programming a microelectronic structure, the method comprising the steps of:
providing a programmable structure comprising a first electrode, a second electrode, and an ion conductor having a first portion of a first conductivity and a second portion of a second conductivity and coupled to the first and second electrodes; and
applying a forward bias across the first and second electrode to form a conductive region near the more negative of the first and second electrode.

18. The method of claim 17, further comprising the step of performing a read on the microelectronic structure by applying a reverse bias across the first and second electrodes and measuring a resulting current pulse.

19. The method of claim 17, further comprising the step of performing a read on the microelectronic structure during the step of applying.

20. The method of claim 17, wherein the step of applying causes a change in a barrier height of a junction that forms between the ion conductor and one of the first and the second electrodes.

21. The method of claim 17, wherein the step of applying causes a change in a contact resistance between the ion conductor and one of the first and the second electrodes.

22. The method of claim 17, further comprising the step of erasing the microelectronic structure by applying a reverse bias across the electrodes, wherein the reverse bias has a magnitude greater than or equal to the forward bias.

23. An array of rows and columns of programmable structures comprising:
a plurality of programmable structures, each structure comprising a first electrode, a second electrode, and an ion conductor; and
a plurality of diodes, wherein at least one diode is coupled to at least one programmable structure.

24. The array of rows and columns of programmable structures of claim 23, wherein the diode comprises a pn junction.

25. The array of rows and columns of programmable structures of claim 23, wherein the diode comprises a Schottky diode.

26. The array of rows and columns of programmable structures of claim 23, wherein at least a portion of the diode is formed within a portion of an insulating layer.

27. A method of forming a programmable structure, the method comprising the step of:
forming an indifferent electrode;
forming an ion conductor having a first portion having a first conductivity and a second portion having a second conductivity; and
forming a soluble electrode.

28. The method of forming a programmable structure of claim 27, wherein the step of forming an ion conductor comprises depositing a layer of conductive material overlying an ion conductive material and causing the conductive material to diffuse within a portion of the ion conductive material.

29. The method of forming a programmable structure of claim 28, wherein the step of forming an ion conductor comprises forming a first portion of the ion conductor with a first concentration of conductive material and a second portion of the ion conductor with a second concentration of conductive material.

30. The method of forming a programmable structure of claim 27, wherein at least one of the steps of forming an indifferent electrode and forming a soluble electrode comprise using interference technology.

31. The method of forming a programmable structure of claim 30, wherein the step of forming an indifferent electrode comprises using interference technology and the step of forming a soluble electrode comprises using interference technology, such that the indifferent electrode and the soluble electrode are rotated with respect to each other.

32. The method of forming a programmable structure of claim 27, wherein at least one of the steps of forming an indifferent electrode and forming a soluble electrode comprise using interference technology to selectively cause diffusion of conductive material into the ion conductor without requiring photoresist.
